(19) United States
(12) Patent Application Publication
(10) Pub. No.: US 2008/0070367 A1
(43) Pub. Date: Mar. 20, 2008

(54) Methods to create dual-gate dielectrics in transistors using high-K dielectric

(76) Inventors: Sangwoo Pae, Beaverton, OR (US); Jose Maiz, Portland, OR (US)

Correspondence Address: INTEL/BLAKELY, 1279 OAKMEAD PARKWAY, SUNNYVALE, CA, 94085-4040, US

(21) Appl. No.: 11/521,638

(22) Filed: Sep. 14, 2006

(51) Int. Cl. H01L 21/336

(52) U.S. Cl. 438/287

(57) ABSTRACT

A method including forming a gate dielectric film on a surface of a substrate; selectively increasing a physical thickness of a gate dielectric including the gate dielectric film in a first area designated for devices to be operated within a first voltage range; forming a first device in the first area; and forming a second device including in a second area. An apparatus and a system including a first and a second set of transistor devices on a substrate, the first set of transistors comprising a gate electrode on a first gate dielectric film, the first gate dielectric film including a physical thickness; and the second set of transistors including a gate electrode on a second gate dielectric film, the second gate dielectric film including a physical thickness that is less than the physical thickness of the first gate dielectric film. Also a system including a microprocessor.

### BACKGROUND

1. Field

Integrated circuit processing.

2. Description of Related Art

One way to improve integrated circuit performance is through scaling the individual devices that comprise the functional units of the integrated circuit. Thus, subsequent generations of integrated circuit generally involve reducing the size of the individual devices on, for example, a semiconductor chip.

The scaling of a transistor device requires consideration of the desired performance of the device. For example, one goal may be to increase the current flow in the semiconductor material of the Metal Oxide Semiconductor Field Effect Transistor (MOSFET). In a scaled MOSFET, the current flow is proportional to the voltage applied to the gate electrode and the capacitance seen at the gate:

I∝C(V-Vₜₕ)

where, I is a measure of the current flow, C is the capacitance, V is the voltage applied to the gate electrode, and Vₜₕ is the threshold voltage of the device.

Increasing voltage and/or capacitance of a MOSFET device to improve current flow can result in an increase in power, P(P∝CV²). While scaling trends seek to increase the current drive in the transistor to enhance the overall performance of a chip, it is also very important to reduce the power for mobile applications. Thus, to increase the current flow through the device without increasing too much power requires an optimization of the gate capacitance and voltage for the given technology generation.

One way to increase the capacitance and improve transistor drive (and performance) is by adjusting the thickness of the gate dielectric. In general, the capacitance is related to the gate dielectric by the following formula:

C=kₒₓ/t_{electrical}

where kₒₓ is the dielectric constant of silicon dioxide (SiO₂) and t_{electrical} is the electrical thickness of the gate dielectric. The electrical thickness of the gate dielectric is greater than the actual physical thickness of the dielectric in most MOSFET semiconductor device due principally to a quantum effect experienced in the channel which causes an area directly below the gate to become insulative as carriers flow through the channel of a semiconductor-based transistor device.

In considering the capacitance effects of the gate dielectric, a consideration of the thickness of gate dielectric is important for other reasons. First, the gate dielectric cannot be too thin as a thin gate dielectric will allow a leakage current from the channel through the gate electrode. At the same time, the gate dielectric cannot be too thick because such a gate structure may produce an undesirable fringe electric field and reduce the performance (or drive current) of transistor device. The desired electric field at the gate is typically perpendicular to the surface of the semiconductor substrate. Beyond a certain gate dielectric thickness, generally thought to be beyond one-third the lateral width of the gate electrode for a SiO₂ gate dielectric, the electrical field deviates from a perpendicular course and sprays about the gate electrode leading to an undesirable fringe electric field.

Finally, the previous discussion focused primarily on devices (e.g., transistor devices) that constitute the functional units of an integrated circuit such as a microprocessor on a chip. The same chip may also include devices that function as input/output (I/O) buffers. Transistor devices that function as I/O buffers interface with components external to the chip. Such transistors may see higher voltages than logic or other functional transistors on the same chip. Transistors with overall thicker electrical or physical thickness of the gate dielectric can sustain higher voltage. Therefore, transistor devices functioning as I/O buffers may require a greater electrical or physical thickness of the gate dielectric than functional transistors on the same chip.

### BRIEF DESCRIPTION OF THE DRAWINGS

FIG. 1 shows a schematic top sectional view of a portion of a chip indicating areas for I/O buffer devices and functional unit devices.

FIG. 2 shows a cross-sectional view of a portion of the substrate of FIG. 1 including an interfacial oxide and a dielectric material film or layer formed thereof.

FIG. 3 shows the structure of FIG. 2 following masking of an area designated for functional unit devices of the substrate.

FIG. 4 shows the structure of FIG. 3 following the creation of additional dielectric material in the areas designated for I/O devices.

FIG. 5 shows the structure of FIG. 4 following the removal of the masking material.

FIG. 6 shows the structure of FIG. 5 with a first transistor device formed in the area designated for I/O buffer devices and a second transistor device formed in the area designated for functional unit device.

FIG. 7 shows a cross-sectional side view of another embodiment of the structure of FIG. 1 having an interfacial oxide and a dielectric layer formed on the surface thereof.

FIG. 8 shows the structure of FIG. 7 following the patterning of a masking material over the portion of the structure designated for functional unit devices and the implantation of a species into the area designated for I/O buffer devices.

FIG. 9 shows the structure of FIG. 8 following the formation of additional dielectric material in the substrate.

FIG. 10 shows the structure of FIG. 9 following the removal of the masking material.

FIG. 11 shows the structure of FIG. 10 following the formation of a first transistor device in an area designated for I/O buffer devices and a second transistor device in an area of the structure designated for functional unit devices.

FIG. 12 shows a cross-sectional side view of another embodiment of the structure of FIG. 1 including an interfacial oxide and a dielectric layer formed on a surface of the substrate.

FIG. 13 shows the structure of FIG. 12 following the formation of an additional dielectric layer on the surface of the substrate and a masking material formed over an area designated for I/O buffer devices.

FIG. 14 shows the structure of FIG. 13 following the removal of the additional dielectric material in an area designated for functional unit devices.

FIG. 15 shows the structure of FIG. 14 following the removal of the masking material.

FIG. 16 shows the structure of FIG. 15 following the formation of a first transistor device in an area designated for I/O buffer devices and a second transistor device in an area designated for functional unit device.

FIG. 17 shows a schematic side view of a computer system including a microprocessor and a chip substrate such as described in the embodiments described with reference to FIGS. 1-16.

### DETAILED DESCRIPTION

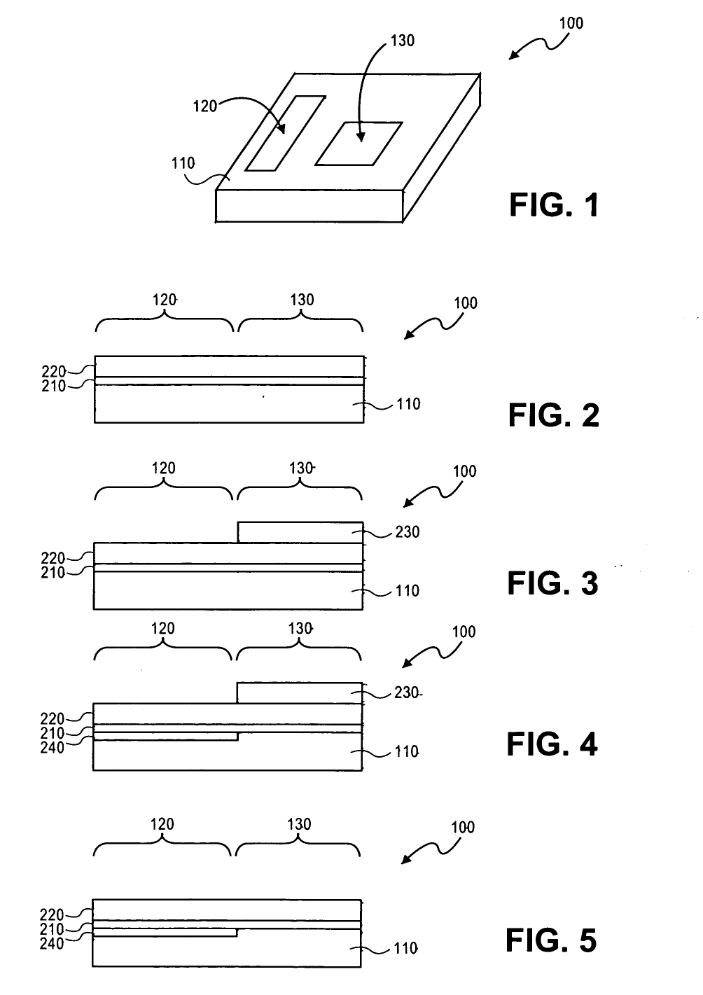

FIG. 1 shows a schematic top sectional view of a portion of an integrated circuit substrate such as a portion of a chip (including, for example, an entire portion). In the representation shown in FIG. 1, structure 100 includes substrate 110 that is, for example, a semiconductor material such as bulk silicon or a silicon-on-insulator (SOI) substrate. In the embodiment shown in FIG. 1, two distinct areas of substrate 110 are designated for devices (e.g., transistor devices). FIG. 1 shows area 120 designated for input/output (I/O) buffer devices to receive and transmit signals to and from structure 100, respectively. Substrate 110 also includes area 130 designated for functional unit devices. In one embodiment, functional unit devices in area 130 may be configured to operate at relatively low voltages (e.g., on the order of 1.5V or less) and I/o buffer devices in area 120 may be configured to operate at higher voltages (e.g., 1.8V or higher).

FIGS. 2-6 show an embodiment of forming transistor devices having different gate dielectric thicknesses in a region including area 120 and a region including area 130, respectively. FIG. 2 shows a cross-sectional side view of structure 100 including the portion containing area 120 and area 130. In one embodiment, substrate 110 in structure 100 is a silicon substrate. Overlying a surface of substrate 110 (a top surface as viewed) is interfacial oxide layer 210 that may be chemically or thermally formed to a thickness on the order of 4 angstroms (Å) to 10 Å. Overlying interfacial oxide layer 210 in the embodiment shown in FIG. 2 is dielectric layer 220. In one embodiment, dielectric layer 220 is a material selected to have a dielectric constant, K, that is greater than silicon dioxide (SiO₂) (a “high-K dielectric material”). In one embodiment, a material for dielectric layer 220 also has a heat of formation greater than heat of formation of SiO₂. Examples of suitable materials for dielectric layer 220 include, but are not limited to, hafnium oxide (HfO₂), hafnium silicon oxide (HfSiO), zirconium oxide (ZrO₂), barium oxide (BaO), lanthanum oxide (La₂O₃), and yttrium oxide (Y₂O₃) and their nitrided oxides. High-k gate dielectric layer 220 can be formed by any suitable method known in the art such as, but not limited to, chemical vapor deposition (CVD), physical vapor deposition (PVD), and atomic layer deposition (ALD). For an embodiment, high-k gate dielectric 220 is formed by exposing the semiconductor substrate 110 to alternating metal-containing precursors and oxygen-containing precursors until a layer, having the desired thickness, is formed. For example, hafnium tetrachloride, lanthanum trichloride, and water and exemplary metal and oxygen precursors may be used to form high-k gate dielectric layer 220. A suitable thickness of dielectric layer 220 for purposes of serving as a gate dielectric is on the order of 15 Å to 30 Å. In the embodiment shown in FIG. 2, interfacial oxide layer 210 and dielectric layer 220 are formed over a surface of substrate 110 including over regions denoted by area 120 and area 130 as described with reference to FIG. 1.

FIG. 3 shows the structure of FIG. 2 following the deposition and patterning of sacrificial masking material layer 230 over area 130. In this embodiment, masking material layer 230 is a material that will inhibit oxidation of the underlying substrate (e.g., the underlying silicon of substrate 110) upon exposure to a subsequent high temperature anneal. For one embodiment, masking material 230 includes polycrystalline silicon (polysilicon). In addition to polysilicon, masking layer material may include any material such that a mask for an underlying silicon of substrate 110 is achieved and such that it can withstand high temperatures during a dielectric stack anneal. Such examples are, but not limited to, sputtered silicon, and silicon nitride films. Sacrificial masking layer 230 may be patterned using photolithographic techniques. In the embodiment shown, sacrificial masking layer 230 is patterned to mask a region including area 130 of structure 110 while leaving a region including area 120 exposed.

FIG. 4 shows the structure of FIG. 3 following the formation of oxide layer 240 in substrate 110. In the embodiment where substrate 210 is a silicon material, dielectric layer 240 may be a SiO₂ layer (additional interfacial oxide) formed by annealing structure 100 in an oxygen or nitrogen/oxygen ambient in combination with high temperatures. A duration of any anneal will determine the thickness of dielectric layer 240. For one embodiment, this anneal is 850-1000° C. spike anneals done in Rapid Thermal Processing (RTP) chamber (with a temperature ramp rate of ˜150° C./sec) in nitrogen/oxygen or oxygen ambient. For purposes of illustration, interfacial oxide layer 210 and dielectric layer 240 are shown as distinct layers in a region of substrate 110 corresponding to area 120. It is appreciated that, where each of interfacial oxide layer 210 and dielectric layer 240 are interfacial oxide material, a demarcation of distinct layers may not be evident.

FIG. 5 shows the structure of FIG. 4 following the removal of sacrificial masking layer 230. Following the removal of masking layer 230, structure 100 includes composite dielectric material layers of different thicknesses in regions including area 130 and area 120, respectively. As illustrated in FIG. 5, a region including area 120 of structure 100 includes interfacial oxide layer 210, dielectric layer 220 and dielectric layer 240. A region including area 130 of structure 100 includes interfacial oxide layer 210 and dielectric layer 220. The thickness of dielectric layer 220 is essentially unchanged throughout the processing.

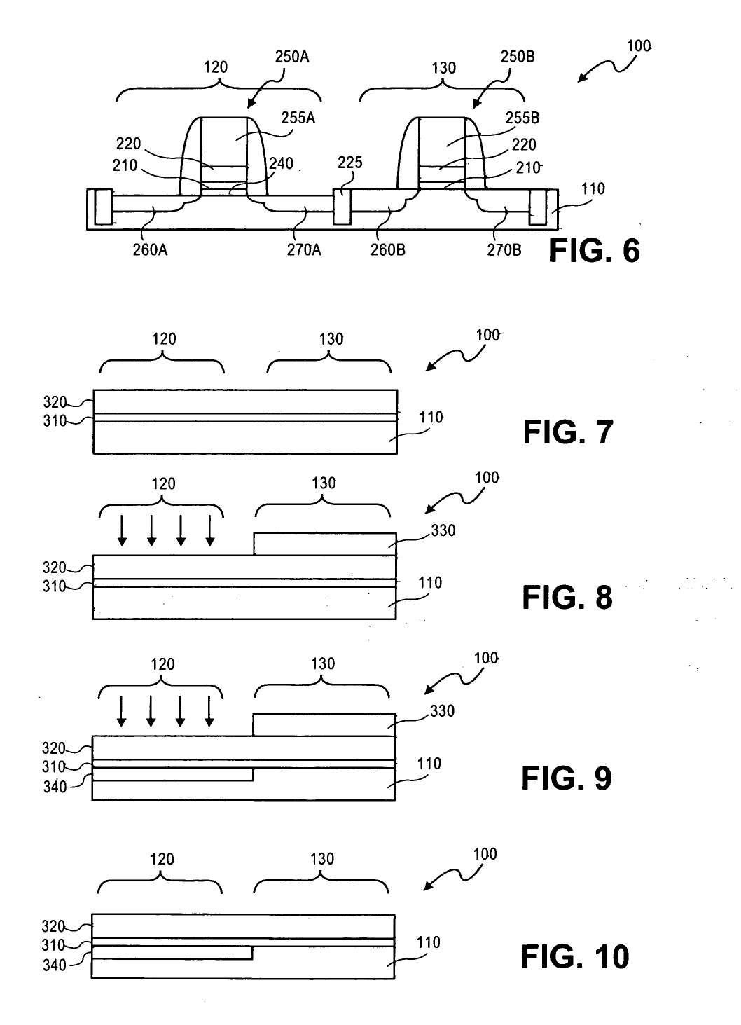

FIG. 6 shows the structure of FIG. 5 following the formation of transistor devices in and on substrate 110. In a region including area 120 of structure 100, a transistor device includes gate electrode 255A formed over a composite gate dielectric including interfacial oxide layer 210, dielectric layer 220 and dielectric layer 240. Transistor device 250A also includes source region 260A and drain region 270A formed in substrate 110 on opposite sides of gate electrode 255A to define a channel in the substrate. An area designated for transistor device 250A is isolated by shallow trench isolation structure 225.

FIG. 6 also shows transistor device 250B formed in area 130 of structure 100. For illustrative purposes, transistor 250B in a region including area 130 is shown adjacent to transistor 250A in a region including area 120. It is appreciated that such transistors need not be adjacent to each other as shown but may be in different locations (e.g., quadrants) of structure 100. In the embodiment shown in FIG. 6, transistor 250B includes gate electrode 255B formed over a composite gate dielectric of interfacial oxide layer 210 and dielectric layer 220. Thus, the composite gate dielectric for transistor 250B has a physical thickness less than the composite gate dielectric of transistor 250A. In the embodiment in FIG. 6, transistor 250B also includes source region 260B and drain region 270B formed in substrate 110 on opposite sides.

FIGS. 7-11 show another embodiment of forming transistor devices having different gate dielectric thicknesses on the same chip. Referring to FIG. 7, in this embodiment, structure 100 includes interfacial oxide layer 310 formed on a surface of substrate 110 (a top surface as shown). In an embodiment where substrate 110 includes a silicon material, interfacial oxide layer 310 may be thermally grown or chemically deposited to a desired thickness (e.g., 4-10 Å). Overlying interfacial oxide layer 310 on substrate 110 of FIG. 7 is dielectric layer 320. In one embodiment, dielectric layer 320 is a high-K dielectric material similar to the high-K dielectric material described with reference to dielectric layer 220 of the embodiment described with reference to FIGS. 1-6. In one embodiment, interfacial oxide layer 310 and dielectric layer 320 are formed on substrate 110 including regions designated by area 120 and area 130.

FIG. 8 shows the structure of FIG. 7 following the deposition and patterning of sacrificial masking layer 330 on dielectric layer 320. For one embodiment, masking material 330 includes polysilicon. In addition to polysilicon, masking layer material may include any material such that a mask for an underlying silicon of substrate 110 is achieved and such that it can withstand high temperatures during a dielectric stack anneal. Such examples are, but not limited to, sputtered silicon, and silicon nitride films. As shown, sacrificial masking layer 330 is patterned, such as through photolithographic techniques, to mask a region of structure 100 corresponding to area 130 thus leaving area 120 exposed.

FIG. 8 also shows the implantation of a dopant species into substrate 110 in a region designated by area 120. In one embodiment, a suitable dopant species is fluorine introduced at a dopant concentration on the order of 1×10¹⁵ to 5×10¹⁵ atoms/square centimeters (cm²). The fluorine is doped at an energy of 9 kilo-electron volts (keV) to 15 keV such that the fluorine is driven into interfacial region of substrate 110 and creates additional interfacial oxides on an additional thermal anneal in a forming gas ambient (FGA) or nitrogen/oxygen ambient. Fluorine is known to displace any weak Silicon-to-Oxygen (Si—O) bonds and form stronger Silicon-to-Fluorine (Si—F) bonds, thereby allowing released Oxygen species to diffuse down to the substrate to grow additional physical oxides upon annealing. Masking layer 330 is sufficiently thick so as to block the fluorine penetration into the underlying dielectrics 320, 310 in area 130.

FIG. 9 shows the structure of FIG. 8 following the creation of interfacial oxide layer 340 in substrate 110. Interfacial oxide layer 340 provides an additional material layer to that of interfacial oxide layer 310. The dopant concentration or dose and energy may be optimized to control a desired thickness of interfacial oxide layer 340.

FIG. 10 shows the structure of FIG. 9 following the removal of sacrificial masking layer 330. As illustrated in FIG. 10, the thickness of dielectric material (a composite dielectric) in a region corresponding to area 120 of structure 100 is greater than a thickness of dielectric material in a region corresponding to area 130. The greater thickness of the composite dielectric material in a region denoted by area 120 is due to the addition of interfacial oxide layer 340.

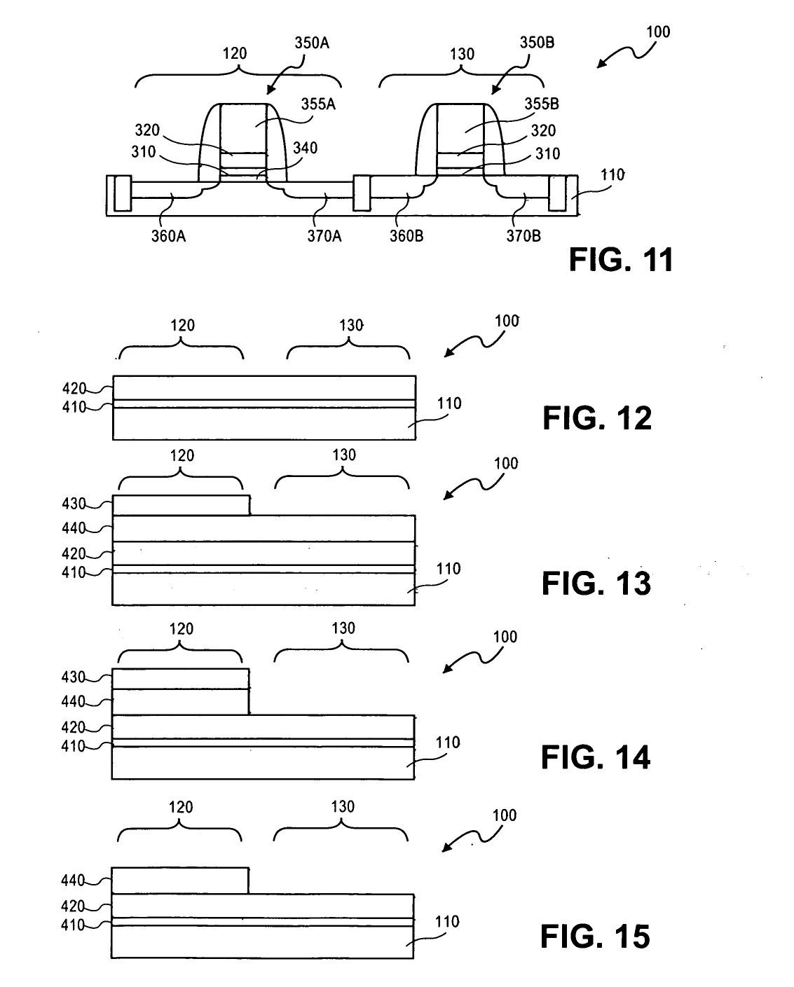

FIG. 11 shows structure 100 following the formation of transistor devices in/on the substrate in regions identified by area 120 and area 130, respectively. As illustrated, the transistor devices in area 120 and area 130 are shown adjacent to one another. It is appreciated that area 120 and area 130 may not be directly adjacent to one another but may be separated on different portions of substrate 110. Referring to FIG. 11, transistor device 350A includes gate electrode 355A formed on a composite gate dielectric of interfacial oxide layer 310, dielectric layer 320 and interfacial oxide layer 340. Transistor 350A also includes source region 360A and drain region 370A formed in substrate 110 on opposite sides of gate electrode 355A to define a channel in the substrate beneath the gate electrode.

FIG. 11 also shows transistor 350B including gate electrode 355B formed on a gate dielectric of interfacial oxide layer 310 and dielectric layer 320. Thus, the gate dielectric for transistor 350B has a physical thickness less than the gate dielectric for transistor 350A. Transistor 350B also includes source region 360B and drain region 370B formed on substrate 110 on opposite sides of gate electrode 355B and defining a channel in the substrate beneath the gate electrode.

FIGS. 12-16 show another embodiment of a method of forming transistor devices having gate dielectrics of different physical thicknesses on a substrate such as a chip.

Referring to FIG. 12, in this embodiment, structure 100 includes substrate 110 of, for example, a semiconductor material such as silicon. Overlying a surface of substrate 110 (a top surface as viewed) is an interfacial oxide layer 410 that may be thermally grown or chemically deposited to a thickness on the order of 4-10 Å. Overlying interfacial oxide layer 410 is dielectric layer 420. In one embodiment dielectric layer 420 is a high-K dielectric material such as described above with reference to FIGS. 1-6, deposited to a thickness on the order of 15-30 Å. As shown in FIG. 12, interfacial oxide layer 410 and dielectric layer 420 are each formed over regions of substrate 110 including area 120 and area 130.

FIG. 13 shows the structure of FIG. 12 following the deposition of dielectric layer 440 on an exposed surface of dielectric layer 420 (an upper surface as viewed). In an embodiment where dielectric layer 420 is a high-K dielectric material and devices to be formed in a region denoted by area 120 are to be I/O buffer devices permitting relatively high voltages, dielectric layer 440 may be a silicon dioxide material deposited, for example, to a thickness on the area of 15 Å or more by known techniques, such as, for example, chemical vapor deposition (CVD).

FIG. 13 shows the structure of FIG. 12 following the formation and patterning of sacrificial masking layer 430 on an exposed surface of dielectric layer 440. In one embodiment, sacrificial masking layer 440 may be a photoresist deposited and patterned to mask an area of dielectric layer 440 corresponding to area 120 while leaving area 130 exposed.

FIG. 14 shows the structure of FIG. 13 following the removal of dielectric layer 440 in an area corresponding to area 130. Where dielectric layer 440 is a silicon dioxide, the silicon dioxide material may be removed by a chemical etch such as with hydrofluoric acid (HF) or other types of chemical etchant that is highly selective between dielectric layers 440 and 420.

FIG. 15 shows the structure of FIG. 14 following the removal of sacrificial masking layer 430. In an embodiment where sacrificial masking layer 430 is a photoresist, the photoresist material may be removed by oxygen ashing. As shown in FIG. 15, structure 100 includes interfacial oxide layer 410, dielectric layer 420 and dielectric layer 440 in a region corresponding to area 120 of the substrate and includes interfacial oxide layer 410 and dielectric layer 420 in a region designated by area 130.

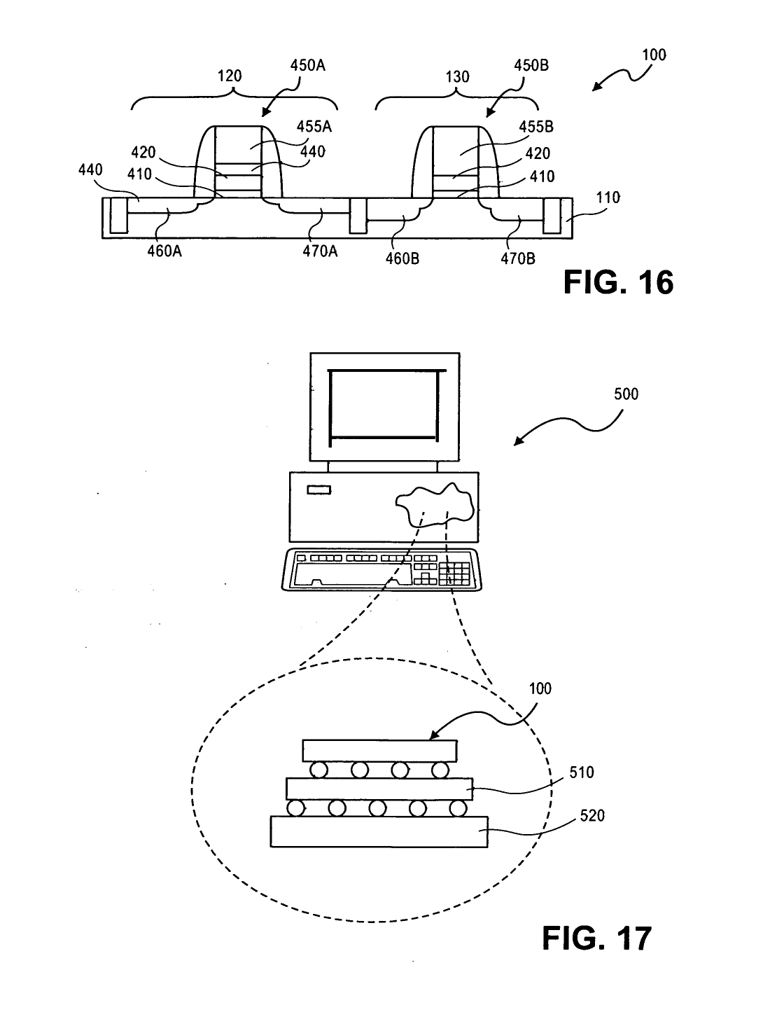

FIG. 16 shows the structure of FIG. 15 following the formation of transistor devices in/on substrate 110 and regions corresponding to area 120 and area 130, respectively. As shown in FIG. 16, transistor devices are shown directly adjacent to one another in the different areas. It is appreciated that the areas may not be directly adjacent to one another on a substrate such as a chip but may be a distance from one another.

Referring to FIG. 16, in a region corresponding to area 120, transistor device 450A includes gate electrode 455A formed over a composite gate dielectric of interfacial oxide layer 410, dielectric layer 420 and dielectric layer 440. Transistor 450A also includes source region 460A and drain region 470A formed in substrate 110 on opposite sides of gate electrode 455A defining a channel in substrate 110 between the source and drain regions.

FIG. 16 also shows transistor device 450B formed in a region corresponding to area 130 of structure 100. Transistor 450B includes gate electrode 455B formed on substrate 110 and separated from the substrate by a composite gate dielectric including interfacial oxide layer 410 and dielectric layer 420. Thus, the composite gate dielectric of transistor device 450B has a physical thickness less than the physical thickness of a composite gate dielectric for transistor 450A. Referring again to transistor 450B, the transistor also includes source region 460B and drain region 470B formed in substrate 110 on opposite sides of gate electrode 455B defining a channel in the substrate beneath the gate electrode.

In the preceding detailed description, the invention is described with reference to specific embodiments thereof. It will, however, be evident that various modifications and changes may be made thereto without departing from the broader spirit and scope of the invention as set forth in the claims. The specification and drawings are, accordingly, to be regarded in an illustrative rather than a restrictive sense.

What is claimed:

1. A method comprising:
forming a gate dielectric film on a surface of a substrate;
selectively increasing a physical thickness of a gate dielectric including the gate dielectric film in a first area designated for devices to be operated within a first voltage range;
forming a first device comprising the gate dielectric in the first area; and
forming a second device comprising the gate dielectric film in a second area designated for devices to be operated within a second voltage range.

2. The method of claim 1, wherein prior to selectively increasing a physical thickness of the gate dielectric, the method comprises:
masking the gate dielectric film in an area other than the first area.

3. The method of claim 2, wherein forming the gate dielectric film comprises:
forming a dielectric material having a dielectric constant greater than a dielectric constant of silicon dioxide on a chemically formed or thermally grown silicon dioxide.

4. The method of claim 3, wherein the dielectric material having the dielectric constant greater than a dielectric constant of silicon dioxide is selected from the group consisting of hafnium oxide (HfO₂), hafnium silicon oxide (HfSiO), zirconium oxide (ZrO₂), barium oxide (BaO), lanthanum oxide (La₂O₃), and yttrium oxide (Y₂O₃) and their nitrided oxides.

5. The method of claim 2, wherein selectively increasing a physical thickness of the gate dielectric comprises annealing the substrate.

6. The method of claim 5, wherein annealing comprises annealing in an O₂ or N₂/O₂ ambient.

7. The method of claim 1, wherein selectively increasing a physical thickness of the gate dielectric involves increasing a physical thickness of silicon dioxide close to the substrate and not the high-k dielectric constant film.

8. The method of claim 2, wherein selectively increasing a physical thickness of the gate dielectric comprises introducing a dopant in the designated area.

9. The method of claim 8, wherein the dopant comprises fluorine.

10. The method of claim 9, wherein selectively increasing a physical thickness of the gate dielectric comprises annealing the substrate to drive the dopant into an interfacial silicon dioxide region of the substrate.

11. The method of claim 1, wherein forming the gate dielectric film comprises forming a first gate dielectric film and selectively increasing a physical thickness of the gate dielectric film comprises:
forming a second gate dielectric film on the first gate dielectric film; and
selectively removing the second dielectric film in an area other than the designated area.

12. An apparatus comprising:
a first set of transistor devices on a substrate, the first set of transistors comprising a gate electrode on a first gate dielectric film, the first gate dielectric film comprising a physical thickness; and
a second set of transistor devices on the substrate, the second set of transistors comprising a gate electrode on a second gate dielectric film, the second gate dielectric film comprising a physical thickness that is less than the physical thickness of the first gate dielectric film.

13. The apparatus of claim 12, wherein the second gate dielectric film comprises a material having a dielectric constant greater than a dielectric constant of silicon dioxide.

14. The apparatus of claim 13, wherein the high-k gate dielectric layer comprises a material selected from the group consisting of hafnium oxide (HfO₂), hafnium silicon oxide (HfSiO), zirconium oxide (ZrO₂), barium oxide (BaO), lanthanum oxide (La₂O₃), and yttrium oxide (Y₂O₃) and their nitrided oxides.

15. The apparatus of claim 13, wherein the first gate dielectric film comprises the material of the first gate dielectric film and an additional dielectric material.

16. The apparatus of claim 13, wherein an electrical thickness of the second gate dielectric film comprises 20 angstroms or less and the electrical thickness of the first gate dielectric film comprises 25 angstroms or more.

17. The apparatus of claim 12, wherein the first set of transistor devices are input/output buffers and the second set of transistor devices are functional units.

18. A system comprising:
a computing device comprising a microprocessor, the microprocessor coupled to a printed circuit board through a substrate, the microprocessor comprising:
a first set of transistor devices on a substrate, the first set of transistors comprising a gate electrode on a first gate dielectric film, the first gate dielectric film comprising a physical thickness; and
a second set of transistor devices on the substrate, the second set of transistors comprising a gate electrode on a second gate dielectric film, the second gate dielectric film comprising a physical thickness that is less than the physical thickness of the first gate dielectric film.

19. The system of claim 18, wherein a physical thickness of the second gate dielectric film is less than a physical thickness of the first gate dielectric film.

20. The system of claim 19, wherein an electrical thickness of the second gate dielectric film comprises 20 angstroms or less and the electrical thickness of the first gate dielectric film comprises 25 angstroms or more.

21. The system of claim 18, wherein the first gate dielectric film comprises the material of the first gate dielectric film and an additional dielectric material.

22. The system of claim 18, wherein the first set of transistor devices are input/output buffers and the second set of transistor devices are functional units.

23. The system of claim 18, wherein the second gate dielectric film comprises a material having a dielectric constant greater than a dielectric constant of silicon dioxide.

24. The system of claim 23, wherein the high-k gate dielectric layer comprises a material selected from the group consisting of hafnium oxide (HfO₂), hafnium silicon oxide (HfSiO), zirconium oxide (ZrO₂), barium oxide (BaO), lanthanum oxide (La₂O₃), and yttrium oxide (Y₂O₃) and their nitrided oxides.
